(19) United States
(12) Patent Application Publication
(10) Pub. No.: US 2025/0062255 A1
(43) Pub. Date: Feb. 20, 2025

(54) SEMICONDUCTOR CHIP AND SEMICONDUCTOR PACKAGE INCLUDING THE SAME

(71) Applicant: SAMSUNG ELECTRONICS CO., LTD., Suwon-si (KR)

(72) Inventors: Gyuseong PARK, Suwon-si (KR); Jongmin Lee, Suwon-si (KR); Nara Lee, Suwon-si (KR); Juik Lee, Suwon-si (KR)

(73) Assignee: SAMSUNG ELECTRONICS CO., LTD., Suwon-si (KR)

(21) Appl. No.: 18/670,055

(22) Filed: May 21, 2024

(30) Foreign Application Priority Data
Aug. 18, 2023 (KR) 10-2023-0108261

(51) Int. Cl. H01L 23/00; H01L 25/065

(52) U.S. Cl. CPC H01L 24/05; H01L 25/0657; H01L 2224/02166; H01L 2224/0219; H01L 2224/0401; H01L 2225/06513; H01L 2225/06541

(57) ABSTRACT

A semiconductor chip includes a semiconductor substrate including an active surface and an inactive surface opposite to the active surface, a wiring layer on the active surface, a front connection pad on the wiring layer, a lower protective insulating layer at least partially covering the wiring layer and including a lower opening that exposes at least a portion of the front connection pad, an upper protective insulating layer including an upper opening communicatively coupled to the lower opening on the lower protective insulating layer, a connection terminal coupled to the front connection pad through the lower opening and the upper opening, and an upper cover insulating layer between the connection terminal and the upper protective insulating layer. The upper protective insulating layer includes an organic material. The upper cover insulating layer includes an inorganic material.

### CROSS-REFERENCE TO RELATED APPLICATIONS

This application claims benefit of priority under 35 U.S.C. § 119 to Korean Patent Application No. 10-2023-0108261, filed on Aug. 18, 2023, in the Korean Intellectual Property Office, the disclosure of which is incorporated by reference herein in its entirety.

### BACKGROUND

### 1. Field

The present disclosure relates generally to a semiconductor chip, and more particularly, to a semiconductor chip including a connection terminal and a semiconductor package including the same.

### 2. Description of Related Art

Recently, as demand increases for increased miniaturization, multi-functionalization, and high performance of electronic products, design constraints for reduced form factors and/or weight, increased integration, increased performance, and/or increased speed of semiconductor packages may also increase. Consequently, demand for semiconductor chips capable of implementing systems and/or electronic devices having increased memory bandwidth and/or demand for semiconductor packages including these semiconductor chips is increasing. Typically, a memory bandwidth may be proportional to a data transmission speed and the number of data transmission lines in the electronic device, and thus, the memory bandwidth of the electronic device may be increased by increasing the memory operation speed and/or by increasing the number of data transmission lines. As a result, the number and/or density of connection bumps attached to connection pads of semiconductor chips may need to be increased in order to increase the memory bandwidth of electronic devices.

### SUMMARY

One or more example embodiments of the present disclosure provide a semiconductor chip with improved contact reliability of connection terminals, and a semiconductor package including the same.

Further, one or more example embodiments of the present disclosure provide a semiconductor chip and a semiconductor package including the same.

According to an aspect of the present disclosure, a semiconductor substrate including an active surface and an inactive surface opposite to the active surface, a wiring layer on the active surface, a front connection pad on the wiring layer, a lower protective insulating layer at least partially covering the wiring layer and including a lower opening that exposes at least a portion of the front connection pad, an upper protective insulating layer including an upper opening communicatively coupled to the lower opening on the lower protective insulating layer, a connection terminal coupled to the front connection pad through the lower opening and the upper opening, and an upper cover insulating layer between the connection terminal and the upper protective insulating layer. The upper protective insulating layer includes an organic material. The upper cover insulating layer includes an inorganic material.

According to an aspect of the present disclosure, a semiconductor chip includes a semiconductor substrate, a front connection pad on the semiconductor substrate, a lower protective insulating layer at least partially covering the semiconductor substrate and including a lower opening that exposes at least a portion of the front connection pad, an upper protective insulating layer including an upper opening communicatively coupled to the lower opening on the lower protective insulating layer, a lower cover insulating layer between the lower protective insulating layer and the upper protective insulating layer, a connection terminal coupled to the front connection pad through the lower opening and the upper opening and spaced apart from the upper protective insulating layer, and an upper cover insulating layer between the connection terminal and the upper protective insulating layer. The upper protective insulating layer including an organic material. The upper cover insulating layer including an inorganic material. The connection terminal includes a pillar barrier layer contacting the upper cover insulating layer and the front connection pad, a conductive pillar including a pillar base layer on the pillar barrier layer, and a conductive cap on the conductive pillar.

According to an aspect of the present disclosure, a semiconductor package includes a first semiconductor chip, a connection terminal, a plurality of second semiconductor chips, and an internal connection terminal. The first semiconductor chip includes a first semiconductor substrate including a first active surface and a first inactive surface opposite to the first active surface, a wiring layer on the first active surface, a first front connection pad on the wiring layer, a first rear connection pad on the first inactive surface, a first through electrode electrically coupling the first front connection pad to the first rear connection pad, a lower protective insulating layer at least partially covering the wiring layer and including a lower opening that exposes at least a portion of the first front connection pad, an upper protective insulating layer including an upper opening communicatively coupled to the lower opening on the lower protective insulating layer, a lower cover insulating layer between the lower protective insulating layer and the upper protective insulating layer, and an upper cover insulating layer at least partially covering an upper surface and a side surface of the upper protective insulating layer and side surfaces of the lower protective insulating layer. The upper protective insulating layer including an organic material. The upper cover insulating layer including an inorganic material. The connection terminal is coupled to the first front connection pad through the lower opening and the upper opening and spaced apart from the upper protective insulating layer. The upper cover insulating layer is disposed between the connection terminal and the upper protective insulating layer. Each second semiconductor chip of the plurality of second semiconductor chips includes a second semiconductor substrate including a second active surface and a second inactive surface opposite to the second active surface, a second front connection pad on the second active surface, a second rear connection pad on the second inactive surface, and a second through electrode electrically coupling the second front connection pad to the second rear connection pad. The plurality of second semiconductor chips are sequentially stacked on the first inactive surface of the first semiconductor chip. The internal connection terminal coupling between the second front connection pad of a lowermost second semiconductor chip at a lowermost end from among the plurality of second semiconductor chips and the first rear connection pad, and coupling between the second front connection pad and the second rear connection pad of different second semiconductor chips from among the plurality of second semiconductor chips. The connection terminal includes a pillar barrier layer contacting the upper cover insulating layer and the first front connection pad, a conductive pillar including a pillar base layer on the pillar barrier layer at least partially filling the lower opening and the upper opening, and a conductive cap on the conductive pillar.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1A is a cross-sectional view showing a semiconductor chip, according to some embodiments;

FIG. 1B is a partial enlarged view of portion IB of FIG. 1A, according to some embodiments;

FIGS. 2A to 2H are cross-sectional views sequentially showing a method of manufacturing a semiconductor chip including a connection terminal, according to some embodiments;

FIG. 3 is a partially enlarged view of a semiconductor chip, according to some embodiments;

FIG. 4 is a partially enlarged view of a semiconductor chip, according to some embodiments;

FIGS. 5A to 5E are cross-sectional views sequentially showing a method of manufacturing a semiconductor chip including a connection terminal, according to some embodiments;

FIG. 6 is a partially enlarged view of a semiconductor chip, according to some embodiments;

FIG. 7 is a cross-sectional view showing a semiconductor package, according to some embodiments; and

FIG. 8 is a cross-sectional view showing a system including a semiconductor package, according to some embodiments.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, and the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

The embodiments herein may be described and illustrated in terms of blocks, as shown in the drawings, which carry out a described function or functions. These blocks, which may be referred to herein as units or modules or the like, or by names such as device, logic, circuit, controller, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, and the like.

As used herein, each of the terms “GaAs”, “InAs”, “InP”, “SiC”, “SiCOH”, “SiN”, “SiO”, “SiOC”, “SnAg”, “TaN”, “TiN”, and the like may refer to a material made of elements included in each of the terms and is not a chemical formula representing a stoichiometric relationship.

Hereinafter, various embodiments of the present disclosure are described with reference to the accompanying drawings.

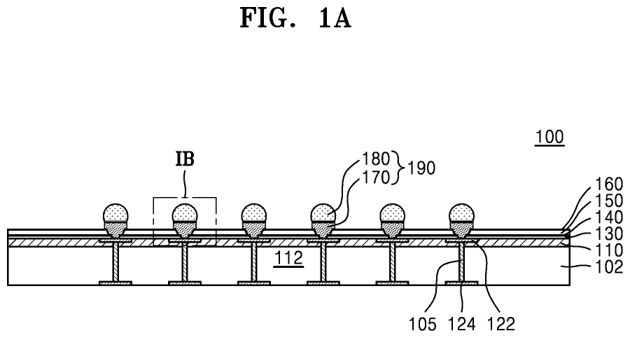

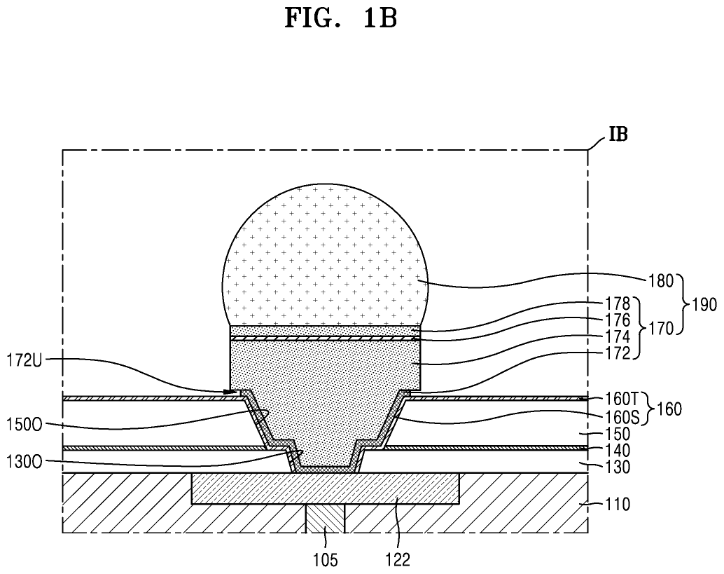

FIG. 1A is a cross-sectional view showing a semiconductor chip 100, according to some embodiments. FIG. 1B is a partial enlarged cross-sectional view showing portion IB of FIG. 1A, according to some embodiments.

Referring to FIGS. 1A and 1B together, the semiconductor chip 100 may include a semiconductor substrate 102, a plurality of front connection pads 122 disposed on an active surface side which is an upper surface of the semiconductor substrate 102, and a plurality of rear connection pads 124 disposed on an inactive surface side which is a lower surface of the semiconductor substrate 102.

The semiconductor substrate 102 may include, for example, a semiconductor material such as silicon (Si). Alternatively or additionally, the semiconductor substrate 102 may include another semiconductor element such as, but not limited to, germanium (Ge), and/or a compound semiconductor such as, but not limited to, silicon carbide (SiC), gallium arsenide (GaAs), indium arsenide (InAs), indium phosphide (InP), and the like. The semiconductor substrate 102 may include an active surface and an inactive surface opposite to the active surface. The semiconductor substrate 102 may include a conductive region, for example, a well doped with impurities. The semiconductor substrate 102 may have various device isolation structures, such as, but not limited to, a shallow trench isolation (STI) structure.

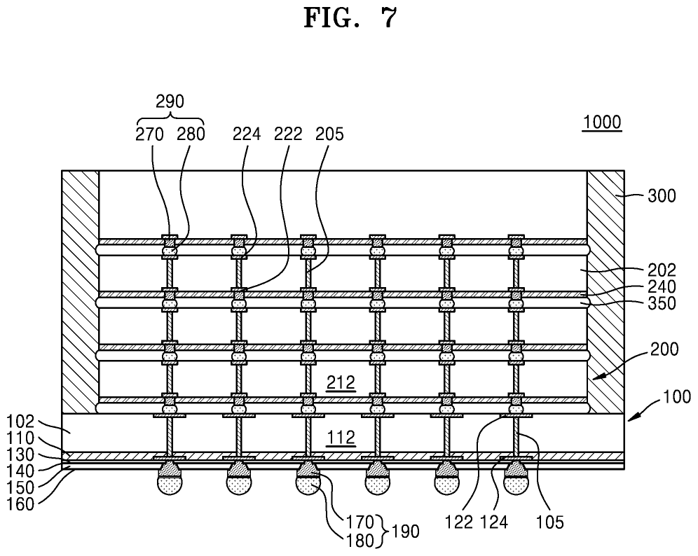

As used herein, upper and lower surfaces may refer to surfaces located at upper and lower sides in the drawings, respectively, and front and rear surfaces may refer to active and inactive surface sides of a semiconductor substrate, respectively. In addition, the terms front and rear may be respectively used for a component disposed on the active surface side of the semiconductor substrate and a component disposed on the inactive surface side. For example, as shown in FIG. 1A, upper and lower surfaces of the semiconductor substrate 102 may be, respectively, an active surface and an inactive surface. As another example, as shown in FIG. 7, the upper and lower surfaces of the semiconductor substrate 102 may be, respectively, an inactive surface and an active surface.

The semiconductor chip 100 may be and/or may include, for example, a dynamic random access memory (DRAM) chip, a static random access memory (SRAM) chip, a flash memory chip, an electrically erasable programmable read-only memory (EEPROM) chip, a phase-change random access memory (PRAM) chip, a magnetic random access memory (MRAM) chip, and/or a resistive random access memory (RRAM) chip. Alternatively or additionally, the semiconductor chip 100 may be and/or may include, for example, a central processing unit (CPU) chip, a graphics processing unit (GPU) chip, and/or an application processor (AP) chip.

In some embodiments, the semiconductor chip 100 may be and/or may include a high bandwidth memory (HBM) DRAM semiconductor chip. In some embodiments, the semiconductor chip 100 may be and/or may include a buffer chip including a serial-parallel conversion circuit. In some embodiments, the semiconductor chip 100 may be and/or may include a buffer chip for controlling a memory chip. When the semiconductor chip 100 is a buffer chip for controlling a memory chip, the semiconductor chip 100 may be referred to as a master chip, and the memory chip may be referred to as a slave chip. Alternatively or additionally, the semiconductor chip 100 may be referred to as a first semiconductor chip.

A semiconductor device 112 may include a plurality of various types of individual devices (not shown) that may be formed on the active surface of the semiconductor substrate 102. The plurality of individual devices may include, but not be limited to, various types of microelectronic devices, such as, but not limited to, metal-oxide-semiconductor field effect transistors (MOSFET) (e.g., complementary metal-oxide-semiconductor (CMOS) transistors), image sensors (e.g., system large scale integration (LSI) and/or CMOS imaging sensors (CIS), micro-electro-mechanical systems (MEMS), active devices, passive devices, and the like. The plurality of individual devices may be electrically connected to the conductive region of the semiconductor substrate 102. The semiconductor device 112 may further include a conductive wiring and/or a conductive plug that may electrically connect at least two of the plurality of individual devices to each other and/or may connect the plurality of individual devices with the conductive region of the semiconductor substrate 102. In some embodiments, each of the plurality of individual devices may be electrically separated from other neighboring individual devices by an insulating layer.

A wiring layer 110 may be disposed on the active surface of the semiconductor substrate 102, and a front connection pad 122 may be disposed on the wiring layer 110. The wiring layer 110 may include a conductive wiring pattern, a conductive wiring via, and an inter-wiring insulating layer surrounding the conductive wiring pattern and the conductive wiring via. The conductive wiring pattern and the conductive wiring via of the wiring layer 110 may electrically connect the semiconductor device 112 to the front connection pad 122. The inter-wiring insulating layer may include an insulating material such as, but not limited to, a tetraethyl ortho silicate (TEOS) oxide layer, Tonen SilaZene (TOSZ), Spin-on-Glass (SOG), undoped silica glass (USG), a low-k dielectric layer, and the like. The low-k dielectric layer may include an insulating material having a lower dielectric constant than silicon dioxide (SiO). In some embodiments, the low-k dielectric layer may include an ultra-low k (ULK) layer having an ultra-low dielectric constant (e.g., about 2.2 to about 2.4). The ULK layer may include, but not be limited to, a silicon oxycarbide (SiOC) layer, a silicon carbon oxygen hydrogen (SiCOH) layer, and the like.

Each of the front connection pad 122 and the rear connection pad 124 may include an electrically conductive material. In some embodiments, each of the front connection pad 122 and the rear connection pad 124 may include, but not be limited to, aluminum (Al).

Although FIGS. 1A and 1B illustrate the front connection pad 122 as being buried in the wiring layer 110, and the rear connection pad 124 as being buried in the semiconductor substrate 102, the present disclosure is not limited thereto. In some embodiments, the front connection pad 122 may protrude from an upper surface of the wiring layer 110, and/or the rear connection pad 124 may protrude from the lower surface (e.g., the inactive surface) of the semiconductor substrate 102.

In an embodiment, the semiconductor substrate 102 may include a base substrate including a semiconductor material, and various conductive material layers and insulating material layers may be formed on the base substrate to constitute the semiconductor device 112. That is, the semiconductor substrate 102 may include a semiconductor material as a main component, and may include other materials in addition to the semiconductor material.

The semiconductor chip 100 may include a plurality of through electrodes 105 electrically connecting each pad of the plurality of front connection pads 122 to a corresponding pad of the plurality of rear connection pads 124. Each of the plurality of through electrodes 105 may penetrate at least a part of the semiconductor substrate 102 between the upper and lower surfaces of the semiconductor substrate 102. The plurality of through electrodes 105 may include a conductive plug penetrating the semiconductor substrate 102 and a conductive barrier layer surrounding the conductive plug. The conductive plug may have a cylindrical shape, and the conductive barrier layer may have a cylindrical shape surrounding side surfaces of the conductive plug. A via insulating layer may be disposed between the semiconductor substrate 102 and the through electrode 105 to surround side surfaces of the through electrode 105.

Although FIG. 1A illustrates the through electrode 105 as directly connecting the front connection pad 122 to the rear connection pad 124, the present disclosure is not limited thereto. In some embodiments, the through electrode 105 may be formed in any one of a via-first, via-middle, and via-last structure. For example, at least a part of the conductive wiring pattern and the conductive wiring via of the wiring layer 110 may be disposed between the through electrode 105 and the front connection pad 122 to electrically connect the through electrode 105 to the front connection pad 122.

On the upper surface of the semiconductor substrate 102, a lower protective insulating layer 130 and an upper protective insulating layer 150 that expose the front connection pad 122 and cover the wiring layer 110 may be sequentially disposed on the wiring layer 110. The lower protective insulating layer 130 may include a lower opening 130O, and the upper protective insulating layer 150 may include an upper opening 150O. The lower opening 130O and the upper opening 150O may be communicatively connected with each other, and the front connection pad 122 may be exposed to a bottom surface of the lower opening 130O. In some embodiments, a horizontal width of the upper opening 150O may be greater than a horizontal width of the lower opening 130O. For example, the maximum horizontal width of the lower opening 130O may be less than the minimum horizontal width of the upper opening 150O. Within the lower opening 130O and the upper opening 150O that are communicatively connected with each other, a part of the lower protective insulating layer 130 may not overlap the upper protective insulating layer 150 in a vertical direction so that the lower protective insulating layer 130 and the upper protective insulating layer 150 may be stacked in a stepped structure.

The upper protective insulating layer 150 may be thicker than the lower protective insulating layer 130. For example, the lower protective insulating layer 130 may have a thickness of about one (1) micrometer (μm) to about four (4) μm. As another example, the upper protective insulating layer 150 may be thicker than the lower protective insulating layer 130 and may have a thickness of about four (4) μm to about eight (8) μm. The horizontal width of the lower opening 130O may be about six (6) μm to about 11 μm. The lower opening 130O may have a tapered shape that may decrease in the horizontal width towards the front connection pad 122. For example, the horizontal width of the lowermost end of the lower opening 130O may be about six (6) μm to about nine (9) μm, and the horizontal width of the uppermost end of the lower opening 130O may be about eight (8) μm to about 11 μm. The horizontal width of the upper opening 150O may be about ten (10) μm to about 20 μm. The upper opening 150O may have a tapered shape that may decrease in the horizontal width towards the lower opening 130O. For example, the horizontal width of the lowermost end of the upper opening 150O may be about ten (10) μm to about 14 μm, and the horizontal width of the uppermost end of the upper opening 150O may be about 16 μm to about 20 μm.

The lower protective insulating layer 130 may include an oxide, an oxynitride, a nitride, and/or a combination thereof. The lower protective insulating layer 130 may include an inorganic material such as, but not limited to, an oxide and/or a nitride. In some embodiments, the lower protective insulating layer 130 may be and/or may include a high density plasma (HDP) oxide layer. Alternatively or additionally, the lower protective insulating layer 130 may include an oxide layer and nitride layer that may be relatively thinner than the oxide layer.

The upper protective insulating layer 150 may include an organic material such as, but not limited to, polymer. In some embodiments, the upper protective insulating layer 150 may include a photosensitive polyimide (PSPI).

The lower cover insulating layer 140 may be disposed between the lower protective insulating layer 130 and the upper protective insulating layer 150. The lower cover insulating layer 140 may extend along the upper surface of the lower protective insulating layer 130 and the lower surface of the upper protective insulating layer 150. The lower cover insulating layer 140 may cover the upper surface of the lower protective insulating layer 130 and the lower surface of the upper protective insulating layer 150. The lower protective insulating layer 130 and the upper protective insulating layer 150 may be spaced apart from each other with the lower cover insulating layer 140 therebetween. The lower cover insulating layer 140 may include a nitride. For example, the lower cover insulating layer 140 may include a silicon nitride (SiN) layer. A thickness of the lower cover insulating layer 140 may be less than one (1) μm. For example, the lower cover insulating layer 140 may have a thickness of about 0.2 μm to about 0.8 μm.

The upper cover insulating layer 160 may cover the upper surface of the upper protective insulating layer 150. The upper cover insulating layer 160 may cover inner surfaces of the upper opening 150O and the lower opening 130O. The upper cover insulating layer 160 may extend from the upper surface of the upper protective insulating layer 150 along the inner surface of the upper opening 150O and the inner surface of the lower opening 130O. For example, the upper cover insulating layer 160 may extend to cover each of the upper surface of the upper protective insulating layer 150, the side surfaces of the upper protective insulating layer 150 within the upper opening 150O, and the side surfaces of the lower protective insulating layer 130 within the lower opening 130O. In some embodiments, the upper cover insulating layer 160 may conformally cover the upper surface of the upper protective insulating layer 150, the inner surface of the upper opening 150O, and the inner surface of the lower opening 130O.

The upper cover insulating layer 160 may include an upper top portion 160T and an upper side portion 160S. The upper top portion 160T may be a portion of the upper cover insulating layer 160 that covers the upper surface of the upper protective insulating layer 150, and the upper side portion 160S may be a portion of the upper cover insulating layer 160 that covers the inner surface of the upper opening 150O and the inner surface of the lower opening 130O. The upper top portion 160T and the upper side portion 160S may be integrally formed. In some embodiments, the upper top portion 160T may cover the entire upper surface of the upper protective insulating layer 150. In some embodiments, the upper side portion 160S may cover both the inner surface of the upper opening 150O and the inner surface of the lower opening 130O. In some embodiments, a thickness of the upper top portion 160T may be substantially similar and/or the same as a thickness of the upper side portion 160S.

In some embodiments, the upper cover insulating layer 160 may contact the lower cover insulating layer 140 at the boundary between the upper opening 150O and the lower opening 130O. The upper cover insulating layer 160 may contact the front connection pad 122 at an edge of the lower opening 130O, but may not extend along the upper surface of the front connection pad 122.

The upper cover insulating layer 160 may include a nitride. For example, the upper cover insulating layer 160 may be and/or may include a silicon nitride (SiN) layer. A thickness of the upper cover insulating layer 160 may be less than one (1) μm. For example, the upper cover insulating layer 160 may have a thickness of about 0.2 μm to about 0.8 μm. In some embodiments, the lower cover insulating layer 140 and the upper cover insulating layer 160 may include the same material. In some embodiments, the lower cover insulating layer 140 and the upper cover insulating layer 160 may have a substantially similar and/or the same thickness.

A plurality of connection terminals 190 may be respectively attached to the plurality of front connection pads 122. Each of the plurality of connection terminals 190 may include a conductive pillar 170 and a conductive cap 180 on the conductive pillar 170. The conductive pillar 170 may be connected to the front connection pad 122 through the upper opening 150O and the lower opening 130O. For example, the conductive pillar 170 may fill the upper opening 150O and the lower opening 130O and may be connected to the front connection pad 122. A lower surface of the conductive pillar 170 may contact the upper surface of the front connection pad 122. The conductive pillar 170 may protrude from the upper opening 150O to the outside (e.g., upward) of the upper opening 150O. For example, the conductive pillar 170 may protrude upward by about 15 μm to about 20 μm from the uppermost end of the upper opening 150O.

The conductive pillar 170 may contact the upper cover insulating layer 160. The conductive pillar 170 may be spaced apart from the upper protective insulating layer 150 and the lower protective insulating layer 130 with the upper cover insulating layer 160 therebetween. The conductive pillar 170 may be spaced apart from the lower cover insulating layer 140 with the upper cover insulating layer 160 therebetween. The upper side portion 160S of the upper cover insulating layer 160 may surround side surfaces of a lower side of the conductive pillar 170. For example, all surfaces of the upper side portion 160S of the upper cover insulating layer 160 facing the upper opening 150O and the lower opening 130O may contact the conductive pillar 170.

The conductive pillar 170 may contact a part of the upper top portion 160T of the upper cover insulating layer 160. For example, a part of the upper top portion 160T of the upper cover insulating layer 160 extending from the upper side portion 160S may contact the conductive pillar 170.

The conductive pillar 170 may include a pillar barrier layer 172, a pillar base layer 174, and a pillar cover layer 176 that may be sequentially stacked. For example, the pillar barrier layer 172 may include, but not be limited to, at least one of titanium (Ti), titanium nitride (TiN), tantalum (Ta), and tantalum nitride (TaN). The upper cover insulating layer 160 may contact the pillar barrier layer 172 of the conductive pillar 170 and may not contact the pillar base layer 174 and the pillar cover layer 176. The pillar base layer 174 may include, but not be limited to, copper (Cu). The pillar cover layer 176 may include, but not be limited to, at least one of nickel (Ni), palladium (Pd), platinum (Pt), and gold (Au). In some embodiments, the pillar cover layer 176 may include, but not be limited to, nickel (Ni). The pillar barrier layer 172 may have a thickness of about 0.5 μm to about 1.5 μm. In some embodiments, a thickness of the pillar barrier layer 172 may be greater than a thickness of the upper cover insulating layer 160. The pillar cover layer 176 may have a thickness of several μm. For example, the pillar cover layer 176 may have a thickness of about two (2) μm to about four (4) μm. The pillar base layer 174 may be formed thicker than the pillar cover layer 176. For example, the pillar base layer 174 may have a thickness of about 18 μm to about 28 μm.

The pillar barrier layer 172 may extend along the bottom and side surfaces of the lower opening 130O and the side surfaces of the upper opening 150O to the upper surface of a partial portion of the upper cover insulating layer 160 covering the upper surface of the upper protective insulating layer 150 and may conformally cover the upper cover insulating layer 160. That is, the pillar barrier layer 172 may cover the front connection pad 122, the upper side portion 160S of the upper cover insulating layer 160, and a part of the upper top portion 160T connected to the upper side portion 160S of the upper cover insulating layer 160.

The pillar base layer 174 may cover the pillar barrier layer 172 and may fill the lower opening 130O and the upper opening 150O. The pillar base layer 174 may fill the lower opening 130O and the upper opening 150O and protrude from the upper opening 150O to the outside (e.g., upward) of the upper opening 150O. The pillar cover layer 176 may cover the upper surface of the pillar base layer 174. A horizontal width of the portion of the pillar base layer 174 that fills the lower opening 130O and the upper opening 150O may be less than a horizontal width of the portion of the pillar base layer 174 protruding from the upper opening 150O.

The horizontal width of the portion of the pillar base layer 174 that fills the lower opening 130O and the upper opening 150O may approach the front connection pad 122 and may decrease in correspondence to the horizontal widths of the lower opening 130O and the upper opening 150O. In some embodiments, the horizontal width of the portion of the pillar base layer 174 that fills the lower opening 130O may be greater than the horizontal width of the portion of the pillar base layer 174 that fills the upper opening 150O. For example, the maximum horizontal width of the portion of the pillar base layer 174 that fills the lower opening 130O may be less than the minimum horizontal width of the portion of the pillar base layer 174 that fills the upper opening 150O.

The portion of the pillar base layer 174 that fills the upper opening 150O may be thicker than the portion of the pillar base layer 174 that fills the lower opening 130O. For example, the portion of the pillar base layer 174 that fills the lower opening 130O may have a thickness of about one (1) μm to about four (4) μm, and the portion of the pillar base layer 174 that fills the upper opening 150O may be thicker than the portion of the pillar base layer 174 that fills the lower opening 130O but may have a thickness of about four (4) μm to about eight (8) μm. The horizontal width of the portion of the pillar base layer 174 that fills the lower opening 130O may be about five (5) μm to about ten (10) μm. The portion of the pillar base layer 174 that fills the lower opening 130O may have a tapered shape that may decrease in the horizontal direction towards the front connection pad 122. For example, the horizontal width of the lowermost end of the portion of the pillar base layer 174 that fills the lower opening 130O may be about five (5) μm to about eight (8) μm, and the horizontal width of the uppermost end of the portion of the pillar base layer 174 that fills the lower opening 130O may be about seven (7) μm to about ten (10) μm. The horizontal width of the portion of the pillar base layer 174 that fills the upper opening 150O may be about nine (9) μm to about 19 μm. The portion of the pillar base layer 174 that fills the upper opening 150O may have a tapered shape that may decrease in the horizontal direction towards the portion of the pillar base layer 174 that fills the lower opening 130O. For example, the horizontal width of the lowermost end of the portion of the pillar base layer 174 that fills the upper opening 150O may be about nine (9) μm to about 13 μm, and the horizontal width of the uppermost end of the portion of the pillar base layer 174 that fills the upper opening 150O may be about 15 μm to about 19 μm.

In some embodiments, the conductive pillar 170 may further include a pillar interface layer 178 covering the pillar cover layer 176. For example, the conductive pillar 170 may include a pillar barrier layer 172, a pillar base layer 174, a pillar cover layer 176, and a pillar interface layer 178 that may be sequentially stacked. The pillar interface layer 178 may include copper (Cu), for example. The pillar interface layer 178 may cover the upper surface of the pillar cover layer 176. A thickness of the pillar interface layer 178 may be substantially similar and/or the same as a thickness of the pillar cover layer 176. For example, the pillar interface layer 178 may have a thickness of about 1.5 μm to about five (5) μm.

Side surfaces of each of the pillar base layer 174, the pillar cover layer 176, and the pillar interface layer 178 may be aligned with each other and extend in one direction. In some embodiments, the side surfaces of each of the pillar base layer 174, the pillar cover layer 176, and the pillar interface layer 178 may be aligned with each other in the vertical direction. The side surfaces of the pillar barrier layer 172 may be shifted toward the inside of the conductive pillar 170 from the side surfaces of each of the pillar base layer 174, the pillar cover layer 176, and the pillar interface layer 178. That is, the side surfaces of each of the pillar base layer 174, the pillar cover layer 176, and the pillar interface layer 178 may be shifted from the side surfaces of the pillar barrier layer 172 to the outside of the conductive pillar 170. An undercut 172U may be located between a part of the upper top portion 160T connected to the upper side portion 160S of the upper cover insulating layer 160 and the pillar base layer 174. The undercut 172U may be limited by a part of the upper top portion 160T of the upper cover insulating layer 160, the pillar base layer 174, and the pillar barrier layer 172.

The conductive cap 180 may cover the conductive pillar 170. A horizontal width of the conductive cap 180 may be greater than the horizontal width of the conductive pillar 170. The conductive cap 180 may include at least one of, tin (Sn), indium (In), bismuth (Bi), antimony (Sb), copper (Cu), silver (Ag), gold (Au), zinc (Zn), and lead (Pb). In some embodiments, the conductive cap 180 may include SnAg.

The plurality of connection terminals 190 included in the semiconductor chip 100 may not contact the upper protective insulating layer 150 and the lower protective insulating layer 130. For example, the conductive pillar 170 of each of the plurality of connection terminals 190 may not contact the upper protective insulating layer 150. In some embodiments, the pillar barrier layer 172 of the conductive pillar 170 may not contact the upper protective insulating layer 150 including PSPI, but may contact the upper cover insulating layer 160 including a silicon nitride layer. The adhesion strength between PSPI and titanium (Ti) is about 2.6 to about 4.7 Joules per square meter (J/m²), the adhesion strength between aluminum (Al) and titanium (Ti) is about five (5) J/m², and the adhesion strength between silicon nitride (SiN) and titanium (Ti) is about 14.2 to about 22.8 J/m². Therefore, in the semiconductor chip 100, the pillar barrier layer 172 of the conductive pillar 170 may contact the upper cover insulating layer 160 having a relatively high adhesion strength without contacting the upper protective insulating layer 150 having a relatively low adhesion strength, and thus, the contact reliability of the plurality of connection terminals 190 may be improved when compared to a related semiconductor chip.

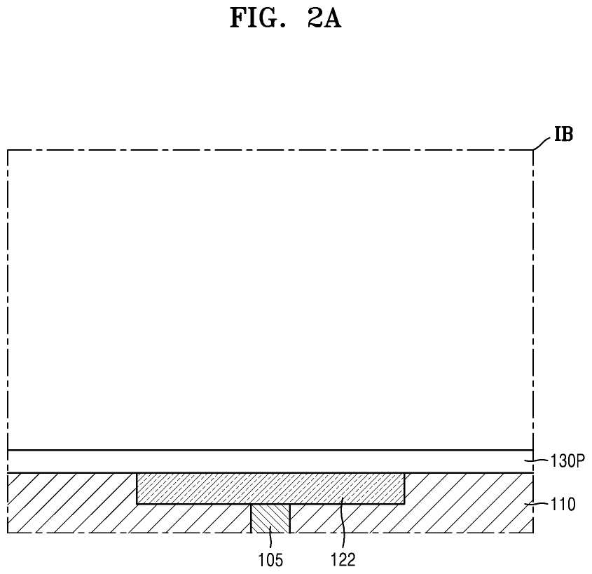

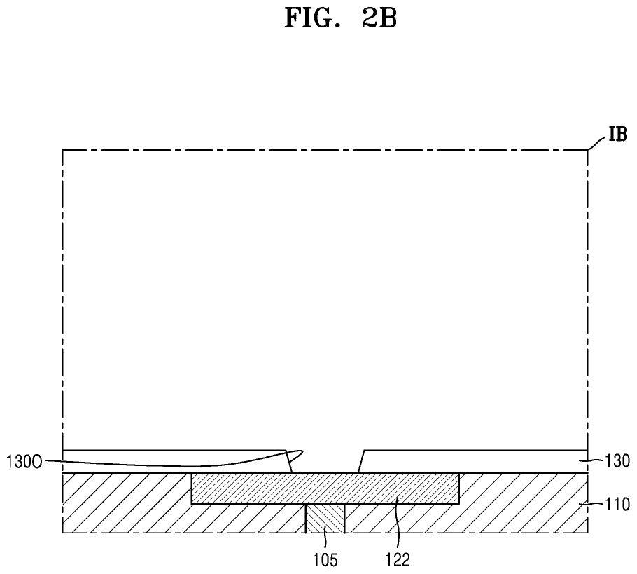

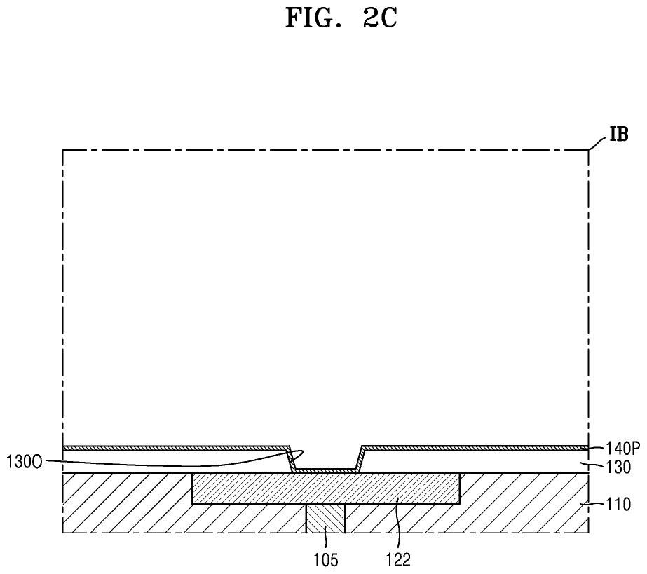

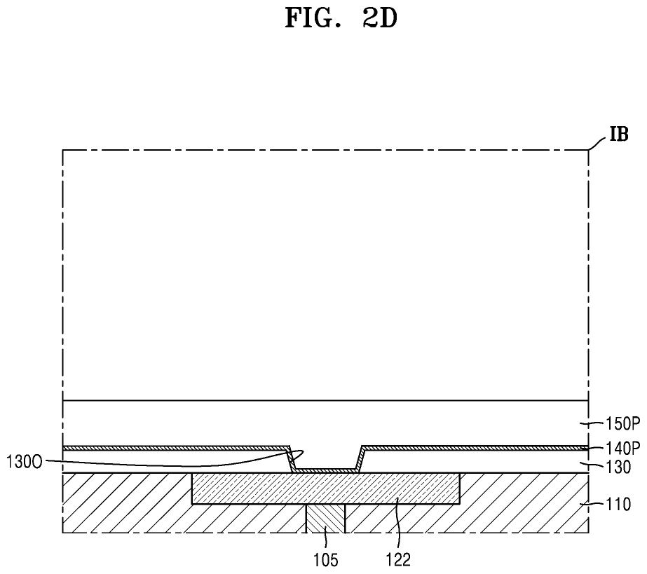

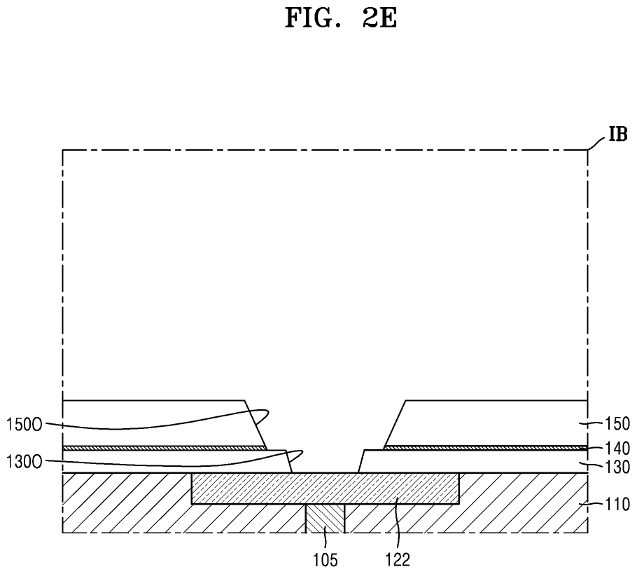

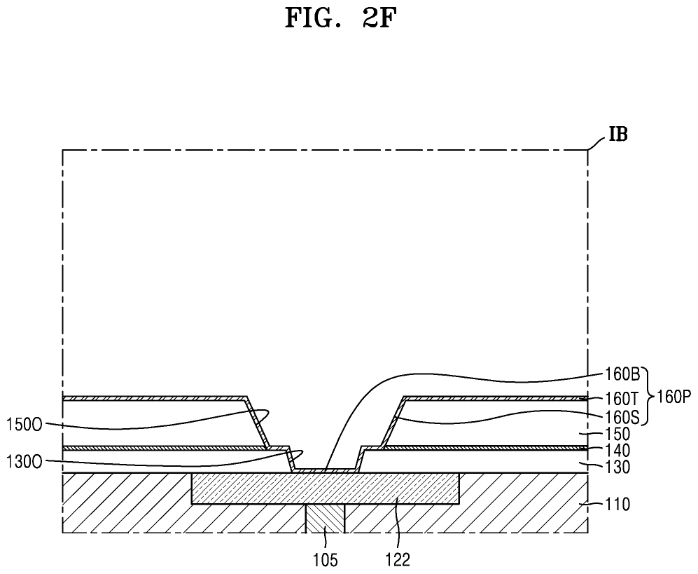

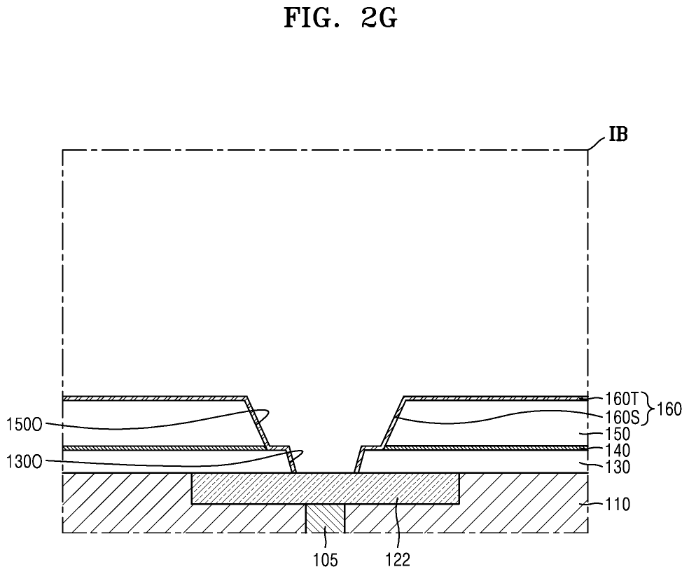

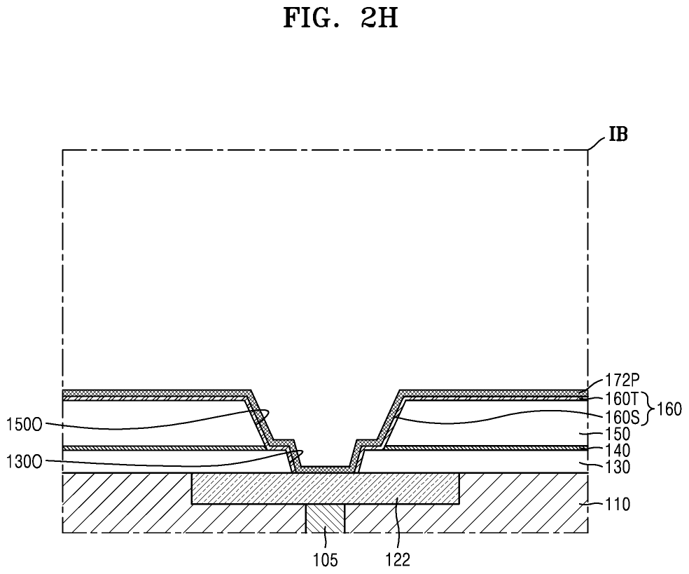

FIGS. 2A to 2H are cross-sectional views sequentially showing a method of manufacturing the semiconductor chip 100 including the connection terminal 190, according to some embodiments. FIGS. 2A to 2H illustrate enlarged cross-sectional views showing portion IB of FIG. 1B, and are described with reference to FIGS. 1A and 1B. Consequently, repeated descriptions of FIGS. 2A to 2H described above with reference to FIGS. 1A and 1B may be omitted for the sake of brevity.

Referring to FIG. 2A, a preliminary lower protective layer 130P may be formed to cover the wiring layer 110 and the front connection pad 122. The preliminary lower protective layer 130P may be formed to cover the entire upper surface of each of the wiring layer 110 and the front connection pad 122. The preliminary lower protective layer 130P may be formed to have a thickness of about one (1) μm to about four (4) μm. The preliminary lower protective layer 130P may include an oxide, an oxynitride, a nitride, and/or a combination thereof. The preliminary lower protective layer 130P may include, but not be limited to, an inorganic material such as an oxide or a nitride.

Referring to FIGS. 2A and 2B together, the lower protective insulating layer 130 including the lower opening 130O may be formed by removing a part of the preliminary lower protective layer 130P. The lower opening 130O may be formed to correspond to the front connection pad 122. An upper surface of the front connection pad 122 may be exposed on a bottom surface of the lower opening 130O.

The lower opening 130O may be formed to have a horizontal width of about six (6) μm to about 11 μm. The lower opening 130O may be formed to have a tapered shape that may decrease in the horizontal width towards the front connection pad 122. For example, the horizontal width of the lowermost end of the lower opening 130O may be about six (6) μm to about nine (9) μm, and the horizontal width of the uppermost end thereof may be about eight (8) μm to about 11 μm. The horizontal width of the lowermost end of the lower opening 130O may be less than or equal to a horizontal width of the front connection pad 122.

Referring to FIG. 2C, a preliminary lower cover layer 140P may be formed to cover the lower protective insulating layer 130 and the front connection pad 122 exposed to the bottom surface of the lower opening 130O. In some embodiments, the preliminary lower cover layer 140P may be formed to conformally cover an upper surface of the lower protective insulating layer 130, side surfaces of the lower protective insulating layer 130 exposed to an inner surface of the lower opening 130O, and an upper surface of the front connection pad 122 exposed to the bottom surface of the lower opening 130O.

The preliminary lower cover layer 140P may include a nitride. For example, the preliminary lower cover layer 140P may include a silicon nitride (SiN) layer. The preliminary lower cover layer 140P may be formed to have a thickness of less than one (1) μm. For example, the preliminary lower cover layer 140P may have a thickness of about 0.2 μm to about 0.8 μm.

Referring to FIG. 2D, a preliminary upper protective layer 150P may be formed to cover the preliminary lower cover layer 140P. The preliminary upper protective layer 150P may be formed to cover the preliminary lower cover layer 140P and completely fill the lower opening 130O. For example, the preliminary upper protective layer 150P may be formed to be thicker than the lower protective insulating layer 130. In some embodiments, the preliminary upper protective layer 150P may have a thickness of about four (4) μm to about eight (8) μm from the upper surface of the lower protective insulating layer 130. The preliminary upper protective layer 150P may include, but not be limited to, an organic material. In some embodiments, the preliminary upper protective layer 150P may include PSPI. The preliminary upper protective layer 150P may be formed to completely cover the preliminary lower cover layer 140P. For example, a lower surface of the preliminary upper protective layer 150P may be formed to contact the upper surface of the preliminary lower cover layer 140P.

Referring to FIGS. 2D and 2E together, the upper protective insulating layer 150 including the upper opening 150O may be formed by removing a part of the preliminary upper protective layer 150P. The upper protective insulating layer 150 may be formed by removing a portion of the preliminary upper protective layer 150P filling the lower opening 130O and a portion of an upper side thereof so that the upper opening 150O may be communicatively connected with the lower opening 130O. In a process of forming the upper protective insulating layer 150, the lower cover insulating layer 140 may be formed by removing a portion of the preliminary lower cover layer 140P exposed to the upper opening 150O. The upper opening 150O may be formed to correspond to the front connection pad 122 and the lower opening 130O. The lower opening 130O and the portion of the upper surface of the front connection pad 122 exposed to the bottom surface of the lower opening 130O may overlap the upper opening 150O in a vertical direction.

In some embodiments, the upper opening 150O may be formed to have a horizontal width greater than the horizontal width of the lower opening 130O. For example, the minimum horizontal width of the upper opening 150O may be greater than the maximum horizontal width of the lower opening 130O. Within the lower opening 130O and the upper opening 150O that are communicatively connected with each other, the lower protective insulating layer 130 and the upper protective insulating layer 150 may be stacked to form a stepped structure. The upper protective insulating layer 150 may be formed to not overlap a part of the lower protective insulating layer 130 adjacent to the lower opening 130O in the vertical direction, and/or to overlap the remaining part of the lower protective insulating layer 130.

The upper protective insulating layer 150 may be formed to have a thickness greater than a thickness of the lower protective insulating layer 130. The upper protective insulating layer 150 may be formed to be thicker than the lower protective insulating layer 130. For example, the upper protective insulating layer 150 may have a thickness of about four (4) μm to about eight (8) μm. The upper opening 150O may be formed to have a horizontal width of about 10 μm to about 20 μm. The upper opening 150O may be formed to have a tapered shape that may decrease in the horizontal width towards the lower opening 130O. For example, the horizontal width of the lowermost end of the upper opening 150O may be about 10 μm to about 14 μm and the horizontal width of the uppermost end thereof may be about 16 μm to about 20 μm.

Referring to FIG. 2F, a preliminary upper cover layer 160P may be formed to cover the upper surface of the upper protective insulating layer 150, inner surfaces of the upper opening 150O and the lower opening 130O, and the front connection pad 122 exposed to the bottom surface of the lower opening 130O. The preliminary upper cover layer 160P may be formed to extend from the upper surface of the upper protective insulating layer 150 along the inner surface of the upper opening 150O and the inner surface and bottom surface of the lower opening 130O. For example, the preliminary upper cover layer 160P may be formed to extend and conformally cover each of the upper surface of the upper protective insulating layer 150, side surfaces of the upper protective insulating layer 150 within the upper opening 150O, side surfaces of the layer 130 within the lower opening 130O, and the upper surface of the front connection pad 122 exposed to the bottom surface of the lower opening 130O.

The preliminary upper cover layer 160P may include the upper top portion 160T, the upper side portion 160S, and an upper bottom portion 160B. The upper top portion 160T may be a portion of the preliminary upper cover layer 160P that covers the upper surface of the upper protective insulating layer 150, the upper side portion 160S may be a portion of the preliminary upper cover layer 160P that covers the inner surface of the upper opening 150O and the inner surface of the lower opening 130O, and the upper bottom portion 160B may be a portion of the preliminary upper cover layer 160P that covers the bottom surface of the lower opening 130O. The upper top portion 160T, the upper side portion 160S, and the upper bottom portion 160B may be integrally formed. In some embodiments, the upper top portion 160T may be formed to cover the entire upper surface of the upper protective insulating layer 150. In some embodiments, the upper side portion 160S may be formed to cover both the inner surface of the upper opening 150O and the inner surface of the lower opening 130O. In some embodiments, the upper bottom portion 160B may be formed to cover the entire bottom surface of the lower opening 130O. In some embodiments, thicknesses of the upper top portion 160T, the upper side portion 160S, and the upper bottom portion 160B may be substantially similar and/or may be the same. In some embodiments, the preliminary upper cover layer 160P may be formed to contact the lower cover insulating layer 140 at the boundary between the upper opening 150O and the lower opening 130O.

The preliminary upper cover layer 160P may be formed to include a nitride. For example, the preliminary upper cover layer 160P may be formed to include a silicon nitride (SiN) layer. The preliminary upper cover layer 160P may be formed to have a thickness of less than one (1) μm. For example, the preliminary upper cover layer 160P may have a thickness of about 0.2 μm to about 0.8 μm.

Referring to FIGS. 2F and 2G together, the upper cover insulating layer 160 may be formed by removing the upper bottom portion 160B of the preliminary upper cover layer 160P. A part of the upper surface of the front connection pad 122 may be exposed through the upper opening 150O and the lower opening 130O.

Referring to FIG. 2H, a preliminary barrier layer 172P may be formed to cover the upper cover insulating layer 160 and a portion of the upper surface of the front connection pad 122 exposed to the bottom surface of the lower opening 130O. The preliminary barrier layer 172P may be formed to conformally cover the upper surface of the upper cover insulating layer 160 and the portion of the upper surface of the front connection pad 122 exposed to the bottom surface of the lower opening 130O. The preliminary barrier layer 172P may be formed to include, but not be limited to, at least one of titanium (Ti), titanium nitride (TiN), tantalum (Ta), and tantalum nitride (TaN). The preliminary barrier layer 172P may be formed to have a thickness of about 0.5 μm to about 1.5 μm. In some embodiments, a thickness of the preliminary barrier layer 172P may be greater (thicker) than a thickness of the upper cover insulating layer 160.

In some embodiments, after forming the preliminary base layer 172P, a preliminary cover layer, and a preliminary interface layer may be formed on the preliminary barrier layer 172P. The conductive pillar 170 including the pillar interface layer 178, the pillar cover layer 176, the pillar base layer 174, and the pillar barrier layer 172 shown in FIGS. 1A and 1B may be formed by patterning the preliminary interface layer, the preliminary cover layer, the preliminary base layer, and the preliminary barrier layer 172P. The conductive cap 180 may be formed on the conductive pillar 170. Accordingly, the semiconductor chip 100 including the connection terminal 190 may be formed.

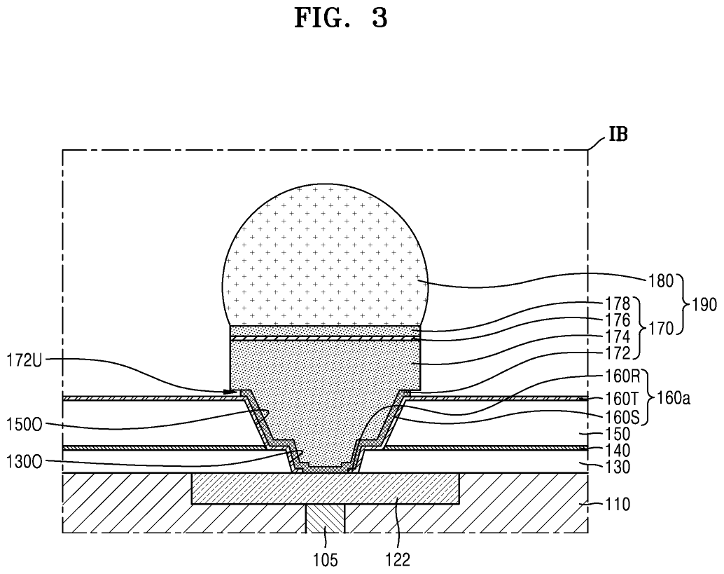

FIG. 3 is a partially enlarged view of the semiconductor chip 100, according to some embodiments. FIG. 3 illustrates an enlarged cross-sectional view showing portion IB of FIG. 1A. Consequently, repeated descriptions of FIG. 3 described above with reference to FIG. 1A may be omitted for the sake of brevity.

Referring to FIGS. 1A and 3 together, the semiconductor chip 100 may include the semiconductor substrate 102, the plurality of front connection pads 122 disposed on an active surface side (e.g., an upper surface) of the semiconductor substrate 102, the plurality of rear connection pads 124 disposed on an inactive surface side (e.g., a lower surface) of the semiconductor substrate 102, and the plurality of through electrodes 105 electrically connecting each pad of the plurality of front connection pads 122 to a corresponding pad of the plurality of rear connection pads 124. Each of the plurality of through electrodes 105 may penetrate at least a part of the semiconductor substrate 102 between the upper and lower surfaces of the semiconductor substrate 102.

On the upper surface of the semiconductor substrate 102, the lower protective insulating layer 130 and the upper protective insulating layer 150 that expose the front connection pad 122 and cover the wiring layer 110 may be sequentially disposed on the wiring layer 110. The lower protective insulating layer 130 may include the lower opening 130O, and the upper protective insulating layer 150 may include the upper opening 150O. The lower opening 130O and the upper opening 150O may be communicatively connected with each other, and the front connection pad 122 may be exposed to a bottom surface of the lower opening 130O. The lower cover insulating layer 140 may be disposed between the lower protective insulating layer 130 and the upper protective insulating layer 150.

An upper cover insulating layer 160a may cover an upper surface of the upper protective insulating layer 150. The upper cover insulating layer 160a may cover the upper opening 150O, an inner surface of the lower opening 130O, and a part of a bottom surface of the lower opening 130O. The upper cover insulating layer 160a may extend from the upper surface of the upper protective insulating layer 150 along the inner surface of the upper opening 150O and the inner surface of the lower opening 130O, and may extend to the bottom surface of the lower opening 130O. For example, the upper cover insulating layer 160a may extend to cover each of the upper surface of the upper protective insulating layer 150, side surfaces of the upper protective insulating layer 150 within the upper opening 150O, and side surfaces of the lower protective insulating layer 130 within the lower opening 130O. Alternatively or additionally, the upper cover insulating layer 160a may extend to cover a part of the upper surface of the front connection pad 122 located on the bottom surface of the lower opening 130O. In some embodiments, the upper cover insulating layer 160a may conformally cover the upper surface of the upper protective insulating layer 150, the inner surface of the upper opening 150O, the inner surface of the lower opening 130O, and a part of the bottom surface of the lower opening 130O.

The upper cover insulating layer 160a may include the upper top portion 160T, the upper side portion 160S, and a bottom residual portion 160R. The upper top portion 160T may be a portion of the upper cover insulating layer 160a that covers the upper surface of the upper protective insulating layer 150, the upper side portion 160S may be a portion of the upper cover insulating layer 160a that covers the inner surface of the upper opening 150O and the inner surface of the lower opening 130O, and the bottom residual portion 160R may be a portion of the upper cover insulating layer 160a that covers a part of the bottom surface of the lower opening 130O.

The upper top portion 160T, the upper side portion 160S, and the bottom residual portion 160R may be integrally formed. In some embodiments, the upper top portion 160T may cover the entire upper surface of the upper protective insulating layer 150. In some embodiments, the upper side portion 160S may cover both the inner surface of the upper opening 150O and the inner surface of the lower opening 130O. The bottom residual portion 160R may be located on the bottom surface of the lower opening 130O and cover a part of the upper surface of the front connection pad 122 adjacent to the upper side portion 160S, and may not cover the entire upper surface of the front connection pad 122. In some embodiments, thicknesses of the upper top portion 160T, the upper side portion 160S, and the bottom residual portion 160R may be substantially similar and/or may be the same.

The upper cover insulating layer 160a may include a nitride. For example, the upper cover insulating layer 160a may be and/or may include a silicon nitride (SiN) layer. A thickness of the upper cover insulating layer 160a may be less than one (1) μm. For example, the upper cover insulating layer 160a may have a thickness of about 0.2 μm to about 0.8 μm. In some embodiments, the lower cover insulating layer 140 and the upper cover insulating layer 160a may include the same material. In some embodiments, the lower cover insulating layer 140 and the upper cover insulating layer 160a may have a substantially similar and/or the same thickness.

The conductive pillar 170 may contact the upper cover insulating layer 160a. The conductive pillar 170 may be spaced apart from the upper protective insulating layer 150 and the lower protective insulating layer 130 with the upper cover insulating layer 160a therebetween. The conductive pillar 170 may be spaced apart from the lower cover insulating layer 140 with the upper cover insulating layer 160a therebetween. The upper side portion 160S and the bottom residual portion 160R of the upper cover insulating layer 160a may surround side surfaces of a lower side of the conductive pillar 170. For example, all surfaces of each of the upper side portion 160S and the bottom residual portion 160R of the upper cover insulating layer 160a facing the upper opening 150O and the lower opening 130O may contact the conductive pillar 170.

The conductive pillar 170 may contact a part of the upper top portion 160T of the upper cover insulating layer 160a. For example, a part of the upper top portion 160T of the upper cover insulating layer 160a extending from the upper side portion 160S may contact the conductive pillar 170.

The conductive pillar 170 may include the pillar barrier layer 172, the pillar base layer 174, and the pillar cover layer 176 that may be sequentially stacked. The pillar barrier layer 172 may extend along the bottom and side surfaces of the lower opening 130O and the side surfaces of the upper opening 150O to the upper surface of a partial portion of the upper cover insulating layer 160a covering the upper surface of the upper protective insulating layer 150 and may conformally cover the upper cover insulating layer 160a. That is, the pillar barrier layer 172 may cover the front connection pad 122, the upper side portion 160S and the bottom residual portion 160R of the upper cover insulating layer 160a, and a part of the upper top portion 160T connected to the upper side portion 160S of the upper cover insulating layer 160a. The undercut 172U may be located between a part of the upper top portion 160T connected to the upper side portion 160S of the upper cover insulating layer 160a and the pillar base layer 174. The undercut 172U may be limited by a part of the upper top portion 160T of the upper cover insulating layer 160a, the pillar base layer 174, and the pillar barrier layer 172.

In a process of removing the upper bottom portion 160B of the preliminary upper cover layer 160P as shown in FIG. 2F, a part of the upper bottom portion 160B adjacent to the upper side portion 160S may remain as the bottom residual portion 160R, and thus, the upper cover insulating layer 160a may be formed.

The plurality of connection terminals 190 included in the semiconductor chip 100 may not contact the upper protective insulating layer 150 and the lower protective insulating layer 130. For example, the conductive pillar 170 of each of the plurality of connection terminals 190 may not contact the upper protective insulating layer 150. In some embodiments, the pillar barrier layer 172 of the conductive pillar 170 may not contact the upper protective insulating layer 150 including PSPI, and may contact the upper cover insulating layer 160a including a silicon nitride layer. Consequently, the pillar barrier layer 172 of the conductive pillar 170 may contact the upper cover insulating layer 160a having a relatively high adhesion strength without contacting the upper protective insulating layer 150 having a relatively low adhesion strength, and thus, the contact reliability of the plurality of connection terminals 190 may be improved when compared to a related semiconductor chip.

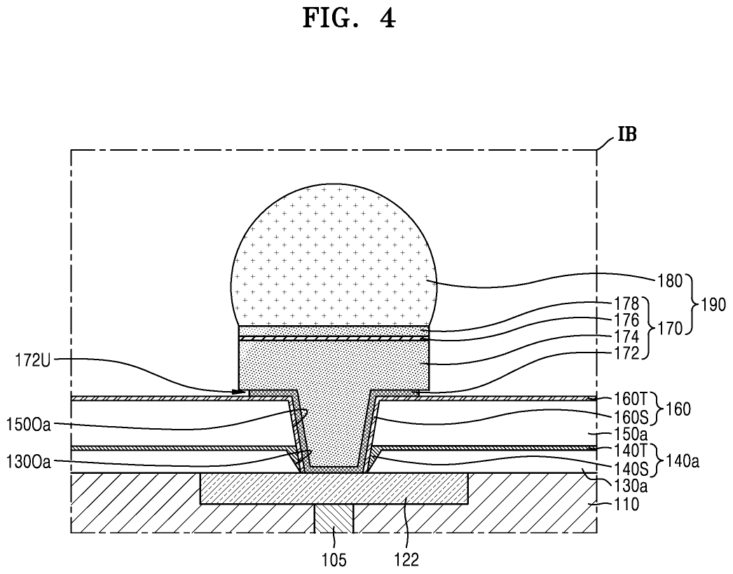

FIG. 4 is a partially enlarged view of the semiconductor chip 100 according to some embodiments. FIG. 4 illustrates an enlarged cross-sectional view showing portion IB of FIG. 1A. Consequently, repeated descriptions of FIG. 4 described above with reference to FIG. 1A may be omitted for the sake of brevity.

Referring to FIGS. 1A and 4 together, the semiconductor chip 100 may include the semiconductor substrate 102, the plurality of front connection pads 122 disposed on an active surface side (e.g., an upper surface) of the semiconductor substrate 102, the plurality of rear connection pads 124 disposed on an inactive surface side (e.g., a lower surface) of the semiconductor substrate 102, and the plurality of through electrodes 105 electrically connecting each pad of the plurality of front connection pads 122 to a corresponding pad of the plurality of rear connection pads 124. Each of the plurality of through electrodes 105 may penetrate at least a part of the semiconductor substrate 102 between the upper and lower surfaces of the semiconductor substrate 102.

On the upper surface of the semiconductor substrate 102, a lower protective insulating layer 130a and an upper protective insulating layer 150a that expose the front connection pad 122 and cover the wiring layer 110 may be sequentially disposed on the wiring layer 110. The lower protective insulating layer 130a may include a lower opening 130Oa, and the upper protective insulating layer 150a may include an upper opening 150Oa. The upper opening 150Oa may penetrate the upper protective insulating layer 150a and a lower cover insulating layer 140a. The upper opening 150Oa may extend into the lower opening 130Oa and may be communicatively connected with the lower opening 130Oa, and the front connection pad 122 may be exposed to bottom surfaces of the lower opening 130Oa and the upper opening 150Oa. In some embodiments, a horizontal width of the lower opening 130Oa may be greater than a horizontal width of the upper opening 150Oa. For example, the maximum horizontal width of the lower opening 130Oa may be greater than the maximum horizontal width of the upper opening 150Oa. For example, the minimum horizontal width of the lower opening 130Oa may be greater than or equal to the minimum horizontal width of the upper opening 150Oa. The upper protective insulating layer 150a may be thicker than the lower protective insulating layer 130a. Each of the lower opening 130Oa and the upper opening 150Oa may have a tapered shape that may decrease in the horizontal width towards the front connection pad 122.

The lower protective insulating layer 130a may include an oxide, an oxynitride, a nitride, and/or a combination thereof. The lower protective insulating layer 130a may include an inorganic material such as, but not limited to, an oxide or a nitride. The upper protective insulating layer 150a may include an organic material, for example.

The lower cover insulating layer 140a may be disposed between the lower protective insulating layer 130a and the upper protective insulating layer 150a. The lower cover insulating layer 140a may extend along an upper surface of the lower protective insulating layer 130a and a lower surface of the upper protective insulating layer 150a and may extend to cover side surfaces of the lower protective insulating layer 130a. The lower protective insulating layer 130a and the upper protective insulating layer 150a may be spaced apart from each other with the lower cover insulating layer 140a therebetween. The lower cover insulating layer 140a may include a nitride. For example, the lower cover insulating layer 140a may include, but not be limited to, a silicon nitride (SiN) layer.

The lower cover insulating layer 140a may include a lower top portion 140T and a lower side portion 140S. The lower top portion 140T may be a portion of the lower cover insulating layer 140a that covers the upper surface of the lower protective insulating layer 130a, and the lower side portion 140S may be a portion of the lower cover insulating layer 140a that covers an inner surface of the lower opening 130Oa. The lower side portion 140S may extend along between the side surfaces of the lower protective insulating layer 130a and the upper side portion 160S. The lower top portion 140T and the lower side portion 140S may be integrally formed. In some embodiments, the lower top portion 140T may cover the entire upper surface of the lower protective insulating layer 130a. In some embodiments, the lower side portion 140S may cover the entire inner surface of the lower opening 130Oa. In some embodiments, a thickness of the lower top portion 140T may be less than the maximum thickness of the lower side portion 140S on the side surfaces of the lower protective insulating layer 130a.

The thickness of the lower top portion 140T of the lower cover insulating layer 140a may be less than one (1) μm. For example, the lower top portion 140T of the lower cover insulating layer 140a may have a thickness of about 0.2 μm to about 0.8 μm. The maximum thickness of the lower side portion 140S of the lower cover insulating layer 140a may be greater than one (1) μm.

The upper cover insulating layer 160 may include the upper top portion 160T and the upper side portion 160S. The upper side portion 160S may extend in a generally constant direction, for example, in a diagonal direction in vertical and horizontal directions, along the side surfaces of the upper opening 150Oa communicatively connected with each other, and cover the side surfaces of the upper protective insulating layer 150a and the lower side portion 140S. For example, the upper side portion 160S may extend from the lowermost end to the uppermost end at a substantially constant acute angle with respect to the front connection pad 122.

The conductive pillar 170 may be connected to the front connection pad 122 through the upper opening 150Oa and the lower opening 130Oa. For example, the conductive pillar 170 may fill the upper opening 150Oa extending into the lower opening 130Oa and may be connected to the front connection pad 122.

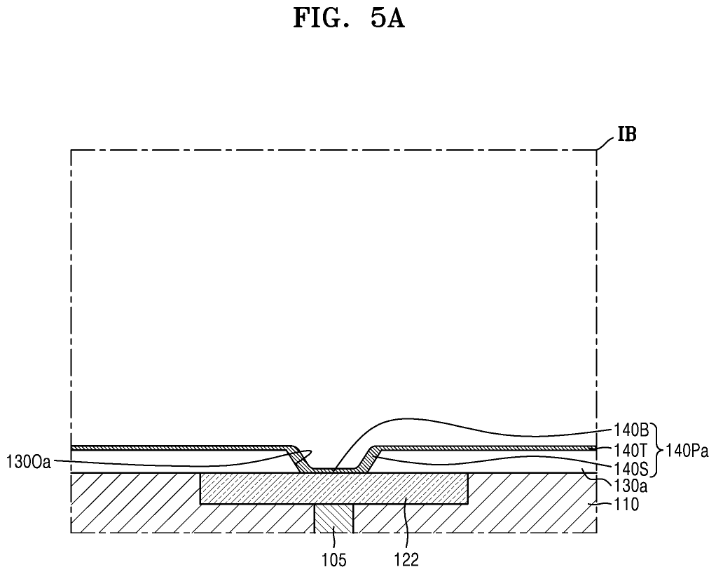

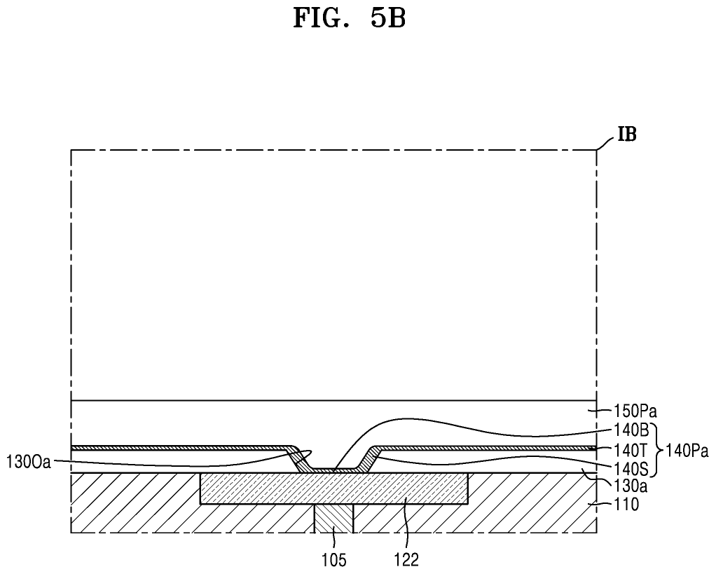

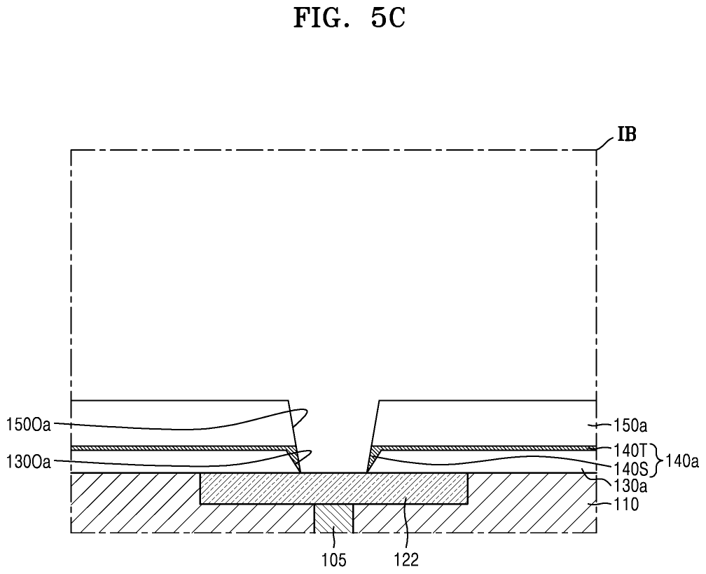

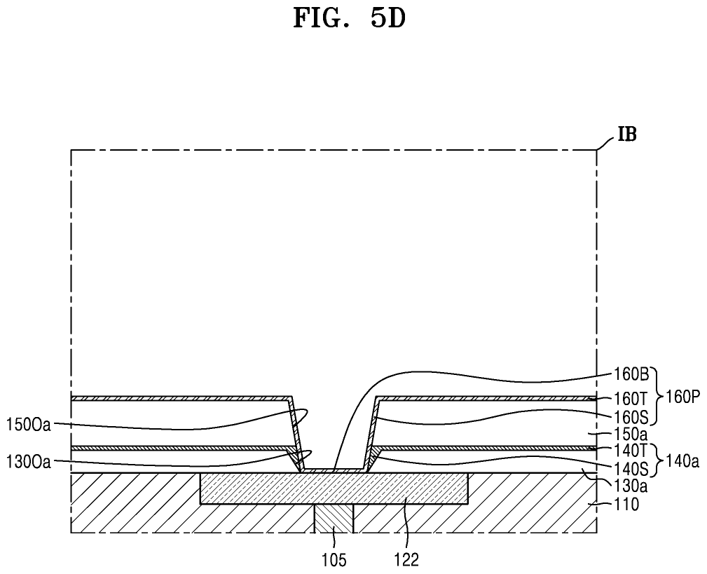

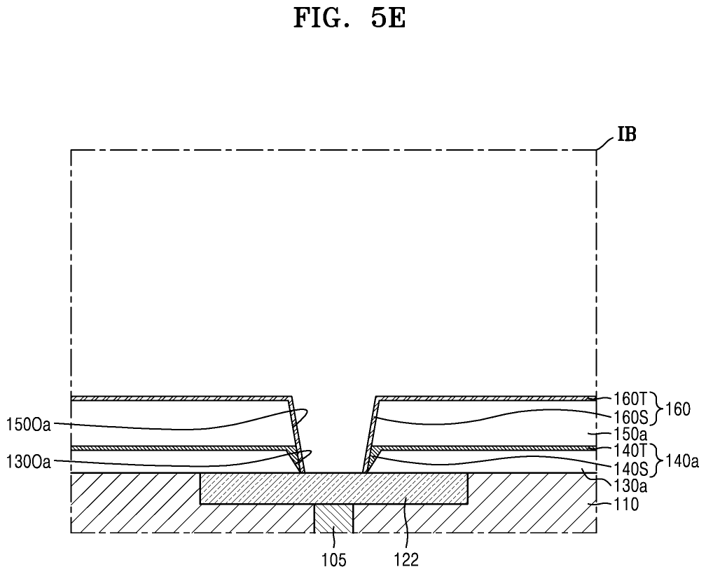

FIGS. 5A to 5E are cross-sectional views sequentially showing a method of manufacturing the semiconductor chip 100 including the connection terminal 190, according to some embodiments, and are described with reference to FIGS. 1A and 4. Consequently, repeated descriptions of FIGS. 5A to 5E described above with reference to FIGS. 1A and 4 may be omitted for the sake of brevity.

Referring to FIG. 5A, the lower protective insulating layer 130a including the lower opening 130Oa may be formed on the wiring layer 110 and the front connection pad 122. The lower protective insulating layer 130a may be formed to cover the entire upper surface of the wiring layer 110 and not cover at least a part of an upper surface of the front connection pad 122. The lower opening 130Oa may be formed to correspond to the front connection pad 122. The upper surface of the front connection pad 122 may be exposed on a bottom surface of the lower opening 130Oa.

A preliminary lower cover layer 140Pa may be formed to cover the lower protective insulating layer 130a and the front connection pad 122 exposed to the bottom surface of the lower opening 130Oa. The preliminary lower cover layer 140Pa may be formed to include a nitride. For example, the preliminary lower cover layer 140Pa may be formed to include a silicon nitride (SiN) layer.

In some embodiments, the preliminary lower cover layer 140Pa may be formed to cover an upper surface of the lower protective insulating layer 130a, side surfaces of the lower protective insulating layer 130a exposed to an inner surface of the lower opening 130Oa, and an upper surface of the front connection pad 122 exposed to the bottom surface of the lower opening 130Oa. The preliminary lower cover layer 140Pa may include the lower top portion 140T, the lower side portion 140S, and a lower bottom portion 140B. The lower top portion 140T may be a portion of the preliminary lower cover layer 140Pa that covers the upper surface of the lower protective insulating layer 130a, the lower side portion 140S may be a portion of the preliminary lower cover layer 140Pa that covers the inner surface of the lower opening 130Oa, and the lower bottom portion 140B may be a portion of the preliminary lower cover layer 140Pa that covers the bottom surface of the lower opening 130Oa. The lower top portion 140T, the lower side portion 140S, and the lower bottom portion 140B may be integrally formed. In some embodiments, the lower top portion 140T may be formed to cover the entire upper surface of the lower protective insulating layer 130a. In some embodiments, the lower side portion 140S may be formed to cover the entire inner surface of the lower opening 130Oa. In some embodiments, the lower bottom portion 140B may be formed to cover the entire bottom surface of the lower opening 130Oa. In some embodiments, the lower side portion 140S may be formed to have a thickness greater than a thickness of the lower top portion 140T.

Referring to FIG. 5B, a preliminary upper protective layer 150Pa may be formed to cover the preliminary lower cover layer 140Pa. The preliminary upper protective layer 150Pa may be formed to cover the preliminary lower cover layer 140Pa and completely fill the lower opening 130Oa.

Referring to FIGS. 5B and 5C together, the upper protective insulating layer 150a including the upper opening 150Oa and the lower cover insulating layer 140a may be formed by removing a part of the preliminary upper protective layer 150Pa and a part of the preliminary lower cover layer 140Pa. The upper opening 150Oa may be formed to penetrate the upper protective insulating layer 150a and the lower cover insulating layer 140a. The lower cover insulating layer 140a may be formed to include the lower top portion 140T and the lower side portion 140S.

The upper opening 150Oa may be formed to extend into the lower opening 130Oa by removing a portion of the preliminary upper protective layer 150Pa filling the lower opening 130Oa and a portion of an upper side thereof, and a partial portion of the preliminary lower cover layer 140Pa filling the lower opening 130Oa. The lower cover insulating layer 140a may be formed by removing the lower bottom portion 140B of the preliminary lower cover layer 140Pa. In some embodiments, the lower cover insulating layer 140a may be formed by removing a part of the lower bottom portion 140B of the preliminary lower cover layer 140Pa and a part of the lower side portion 140S of the preliminary lower cover layer 140Pa.

Referring to FIG. 5D, the preliminary upper cover layer 160P may be formed to cover the upper surface of the upper protective insulating layer 150a, the inner surface of the upper opening 150Oa, and the front connection pad 122 exposed to the bottom surface of the upper opening 150Oa. The preliminary upper cover layer 160P may include the upper top portion 160T, the upper side portion 160S, and an upper bottom portion 160B. The upper top portion 160T may be a portion of the preliminary upper cover layer 160P that covers the upper surface of the upper protective insulating layer 150a, the upper side portion 160S may be a portion of the preliminary upper cover layer 160P that covers the upper protective insulating layer 150a and the lower cover insulating layer 140a located in the inner surface of the upper opening 150Oa, and the upper bottom portion 160B may be a portion of the preliminary upper cover layer 160P that covers the bottom surface of the upper opening 150Oa.

Referring to FIGS. 5D and 5E together, the upper cover insulating layer 160 may be formed by removing the upper bottom portion 160B of the preliminary upper cover layer 160P. A part of the upper surface of the front connection pad 122 may be exposed through the upper opening 150Oa and the lower opening 130Oa.

In some embodiments, the conductive pillar 170 including the pillar interface layer 178, the pillar cover layer 176, the pillar base layer 174, and the pillar barrier layer 172 as shown in FIGS. 1A and 1B may be formed. The conductive cap 180 may be formed on the conductive pillar 170. Accordingly, the semiconductor chip 100 including the connection terminal 190 may be formed.

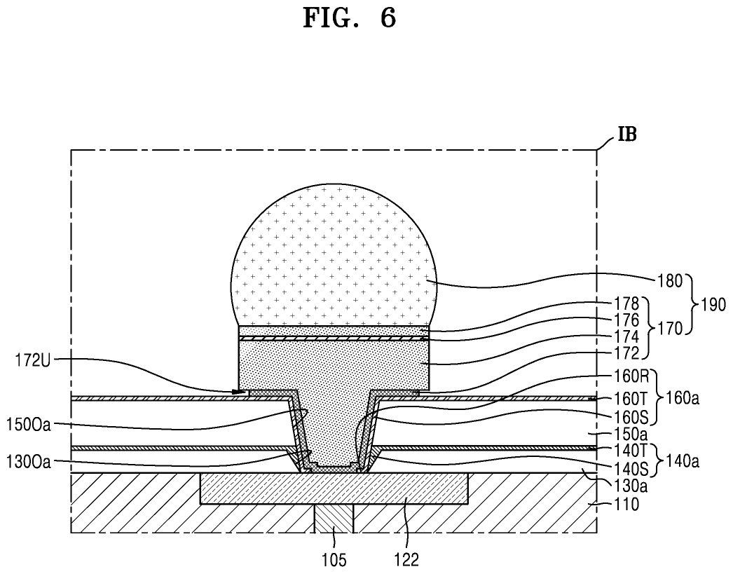

FIG. 6 is a partially enlarged view of the semiconductor chip 100 according to some embodiments. FIG. 6 illustrates an enlarged cross-sectional view showing portion IB of FIG. 1A. Consequently, repeated descriptions of FIG. 6 described above with reference to FIG. 1A may be omitted for the sake of brevity.

Referring to FIGS. 1A and 6 together, the semiconductor chip 100 may include the semiconductor substrate 102, the plurality of front connection pads 122, the plurality of rear connection pads 124, the plurality of through electrodes 105, the lower protective insulating layer 130a including the lower opening 130Oa, the lower cover insulating layer 140a, the upper protective insulating layer 150a including the upper opening 150Oa, the upper cover insulating layer 160a, the conductive pillar 170, and the plurality of connection terminals 190 each including the conductive cap 180 on the conductive pillar 170.

The upper cover insulating layer 160a may include the upper top portion 160T, the upper side portion 160S, and the bottom residual portion 160R. That is, unlike the upper cover insulating layer 160 shown in FIG. 4, the upper cover insulating layer 160a shown in FIG. 6 may further include the bottom residual portion 160R like the upper cover insulating layer 160a shown in FIG. 3. The bottom residual portion 160R may be a portion of the upper cover insulating layer 160a that covers a portion of an upper surface of the front connection pad 122. The bottom residual portion 160R may be located on the bottom surface of the lower opening 130Oa and cover a part of the upper surface of the front connection pad 122 adjacent to the upper side portion 160S, but may not cover the entire upper surface of the front connection pad 122.

In a process of removing the upper bottom portion 160B of the preliminary upper cover layer 160P shown in FIG. 5D, a part of the upper bottom portion 160B adjacent to the upper side portion 160S may remain as the bottom residual portion 160R, and thus, the upper cover insulating layer 160a may be formed.

FIG. 7 is a cross-sectional view showing a semiconductor package 1000, according to some embodiments.

Referring to FIG. 7, the semiconductor package 1000 may include the first semiconductor chip 100 and a plurality of second semiconductor chips 200. Although FIG. 7 illustrates the semiconductor package 1000 as including four (4) second semiconductor chips 200, the present disclosure is not limited thereto. For example, the semiconductor package 1000 may include two or more second semiconductor chips 200. In some embodiments, the semiconductor package 1000 may include a multiple of four (4) second semiconductor chips 200. The semiconductor package 1000 may be referred to as a sub-semiconductor package. The plurality of second semiconductor chips 200 may be sequentially stacked on the first semiconductor chip 100 in a vertical direction. The first semiconductor chip 100 and the plurality of second semiconductor chips 200 may be sequentially stacked with the active surfaces thereof facing downward. For example, the active surfaces of the plurality of second semiconductor chips 200 may be sequentially stacked on an inactive surface of the first semiconductor chip 100.

The first semiconductor chip 100 includes the first semiconductor substrate 102 including the first semiconductor device 112 in an active surface thereof, the wiring layer 110 disposed on the active surface of the first semiconductor substrate 102, the plurality of first upper front connection pads 122 and the plurality of first rear connection pads 124 respectively disposed on the wiring layer 110 and the inactive surface of the first semiconductor substrate 102, the plurality of first through electrodes 105 each penetrating at least a part of the first semiconductor substrate 102 and electrically connecting each pad of the plurality of first upper front connection pads 122 to a corresponding pad of the plurality of first rear connection pads 124, the lower protective insulating layer 130, the lower cover insulating layer 140, the upper protective insulating layer 150, and the upper cover insulating layer 160 that expose at least a part of the plurality of first upper front connection pads 122 and sequentially cover the wiring layer 110, and the plurality of connection terminals 190 attached to the plurality of connection pads 122 and each including the conductive pillar 170 and the conductive cap 180 on the conductive pillar 170.

In some embodiments, the first semiconductor chip 100 may be and/or may include an HBM DRAM semiconductor chip. In some embodiments, the first semiconductor chip 100 may be and/or may include a buffer chip including a serial-parallel conversion circuit. In some embodiments, the first semiconductor chip 100 may be and/or may include a buffer chip for controlling the HBM DRAM semiconductor chip.

The first semiconductor chip 100 shown in FIG. 7 may include and/or may be similar in many respects to the semiconductor chip 100 shown in FIGS. 1A and 1B, and may include additional features not mentioned above. For example, the active surface of the first semiconductor chip 100 may be located on the lower side and the inactive surface may be located on the upper side. That is, the first semiconductor chip 100 of the semiconductor package 1000 may be the semiconductor chip 100 shown in FIGS. 1A and 1B disposed upside down, and the first semiconductor substrate 102, the first semiconductor device 112, the first upper front connection pad 122, the first rear connection pad 124, and the first through electrode 105 may be substantially the same as the semiconductor substrate 102, the semiconductor device 112, the upper front connection pad 122, the rear connection pad 124, and the through electrode 105 shown in FIGS. 1A and 1B, respectively. Consequently, repeated descriptions of FIG. 7 described above with reference to FIGS. 1A and 1B may be omitted for the sake of brevity.

The second semiconductor chip 200 may include a second semiconductor substrate 202 including a second semiconductor element 212 in an active surface of the second semiconductor substrate 202, a plurality of second front connection pads 222 and a plurality of second rear connection pads 224 respectively disposed on an active surface and an inactive surface of a second semiconductor substrate 210, a plurality of second through electrodes 205 each penetrating at least a part of the second semiconductor substrate 202 and electrically connecting the plurality of second front connection pads 222 to the plurality of second rear connection pads 224, and a protective insulating layer 240 exposing at least some of the plurality of second front connection pads 222 and covering the active surface of the second semiconductor substrate 202. The protective insulating layer 240 may include an inorganic material such as, but not limited to, an oxide or a nitride. For example, the protective insulating layer 240 may include at least one of silicon oxide (SiO) and silicon nitride (SiN). In some embodiments, the protective insulating layer 240 may include silicon nitride (SiN). The protective insulating layer 240 may be substantially the same as the lower protective insulating layer 130 shown in FIGS. 1A and 1B, or may be substantially the same as a stack structure of the lower protective insulating layer 130 and the lower cover insulating layer 140. The second semiconductor chip 200 may not include configurations corresponding to the upper protective insulating layer 150 and the upper cover insulating layer 160 included in the first semiconductor chip 100 in the protective insulating layer 240.

The second semiconductor substrate 202, the second front connection pad 222, the second rear connection pad 224, and the second through electrode 205 may be substantially the same as the first semiconductor substrate 102, the first front connection pad 122, the first rear connection pad 124, and the first through electrode 105, respectively, and thus, detailed descriptions thereof may be omitted for the sake of brevity.

The second semiconductor chip 200 may be and/or may include, for example, a DRAM chip, an SRAM chip, a flash memory chip, an EEPROM chip, a PRAM chip, an MRAM chip, or an RRAM chip. In some embodiments, the second semiconductor chip 200 may be and/or may include an HBM DRAM semiconductor chip. The first semiconductor chip 100 may be and/or may include a buffer chip for controlling the second semiconductor chip 200, and the plurality of second semiconductor chips 200 may be memory chips including memory cells. For example, the semiconductor package 1000 including the first semiconductor chip 100 and the plurality of second semiconductor chips 200 may be and/or may include a HBM, and the first semiconductor chip 100 may be referred to as an HBM controller die, and each of the plurality of second semiconductor chips 200 may be referred to as a DRAM die.

An internal connection terminal 290 may be attached to the second front connection pad 222 of each of the plurality of second semiconductor chips 200. The internal connection terminal 290 may electrically connect the first rear connection pad 124 of the first semiconductor chip 100 to the second front connection pad 222 of each of the plurality of second semiconductor chips 200, and may electrically connect the second rear connection pad 224 to the second front connection pad 222 of each of the plurality of second semiconductor chips 200.

The internal connection terminal 290 may include a conductive pillar 270 on the second front connection pad 222 and a conductive cap 280 on the conductive pillar 270. The internal connection terminal 290 may be referred to as a second connection terminal, and the conductive pillar 270 and the conductive cap 280 may be referred to as a second conductive pillar and a second conductive cap, respectively. The connection terminal 190 shown in FIGS. 1A and 1B may be referred to as a first connection terminal, and the internal connection terminal 290 may be referred to as a second connection terminal.

An insulating adhesive layer 350 may be disposed between the first semiconductor chip 100 and each of the plurality of second semiconductor chips 200. The insulating adhesive layer 350 may include, but not be limited to, a non-conductive film (NCF), a non-conductive paste (NCP), an insulating polymer, an epoxy resin, and the like. The insulating adhesive layer 350 may surround the internal connection terminal 290 and fill space between the first semiconductor chip 100 and each of the plurality of second semiconductor chips 200.

In some embodiments, among the plurality of second semiconductor chips 200, the uppermost second semiconductor chip 200 which is farthest from the first semiconductor chip 100 may not include the second rear connection pad 224 and the second through electrode 230. In some embodiments, among the plurality of second semiconductor chips 200, a thickness of the uppermost second semiconductor chip 200 which is farthest from the first semiconductor chip 100 may be less than thicknesses of the remaining second semiconductor chips 200.

A width and area of the first semiconductor chip 100 may be greater than a width and area of each of the plurality of second semiconductor chips 200. The semiconductor package 1000 may further include a molding layer 300 surrounding side surfaces of each of the plurality of second semiconductor chips 200 and side surfaces of the insulating adhesive layer 350 on the first semiconductor chip 100. The molding layer 300 may include, for example, an epoxy mold compound (EMC).

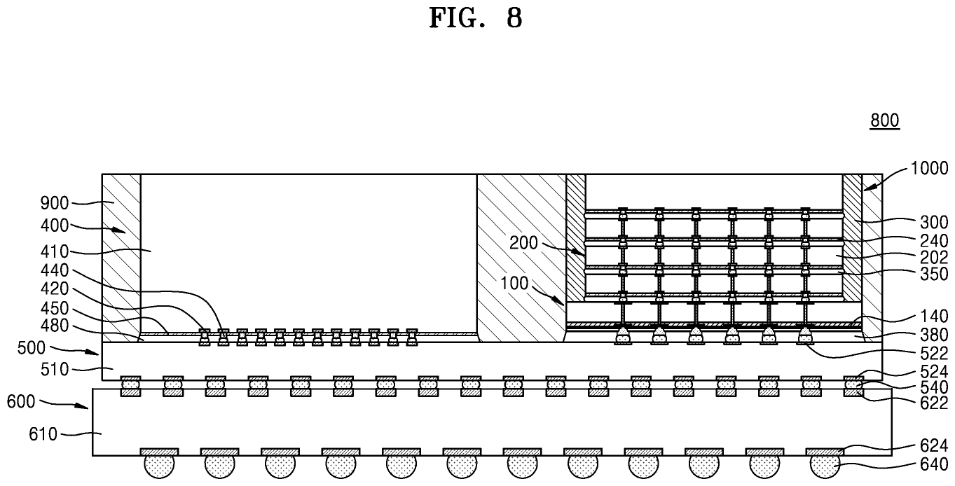

Although FIG. 7 illustrates the semiconductor package 1000 as including the semiconductor chip 100 shown in FIGS. 1A and 1B as the first semiconductor chip 100, the present disclosure is not limited thereto. For example, the semiconductor package 1000 may also include the semiconductor chip 100 shown in FIGS. 1A and 3, the semiconductor chip 100 shown in FIGS. 1A and 4, and/or the semiconductor chip 100 shown in FIGS. 1A and 6. FIG. 8 is a cross-sectional view showing a system 800 including the semiconductor package 1000, according to some embodiments.

Referring to FIG. 8, the system 800 may include a main board 600 on which an interposer 500 may be mounted, the semiconductor package 1000 including the first semiconductor chip 100 attached to the interposer 500 and the plurality of second semiconductor chips 200, and a third semiconductor chip 400. The semiconductor package 1000 has been described with reference to FIG. 7, and thus, repeated descriptions thereof may be omitted for the sake of brevity.

The third semiconductor chip 400 may include a third semiconductor substrate 410, a plurality of third front connection pads 420, a third protective insulating layer 450, and a third connection terminal 440. The third semiconductor substrate 410, the third front connection pad 420, the third protective insulating layer 450, and the third connection terminal 440 may be substantially similar to the second semiconductor substrate 202, the second front connection pad 222, the second protective insulating layer 240, and the second connection terminal 290 shown in FIG. 7, respectively, and thus, detailed descriptions thereof may be omitted for the sake of brevity. For example, similarly to the second conductive pillar 270 and the second conductive cap 280 included in the second connection terminal 290 shown in FIG. 7, the third connection terminal 440 may include a third conductive pillar and a third conductive cap on the third conductive pillar in the third front connection pad 420.

The third semiconductor chip 400 may be and/or may include, for example, a CPU chip, a GPU chip, or an AP chip.

The interposer 500 may include a base layer 510 and a plurality of first upper pads 522 and a plurality of first lower pads 524 disposed on upper and lower surfaces of the base layer 510, respectively.

The base layer 510 may include semiconductor, glass, ceramic, or plastic. For example, the base layer 510 may include silicon. A wiring layer connected to the plurality of first upper pads 522 and/or the plurality of first lower pads 524 may be disposed on the upper and/or lower surface of the base layer 510, and a plurality of internal through electrodes may be formed inside the base layer 510 to electrically connect the plurality of first upper pads 522 to the plurality of first lower pads 524. The first connection terminal 190 in FIG. 7 electrically connecting the semiconductor package 1000 to the interposer 500, and the third connection terminal 440 electrically connecting the third semiconductor chip 400 to the interposer 500 may be connected to the plurality of first upper pads 522.

A first underfill layer 380 may be disposed between the semiconductor package 1000 and the interposer 500, and a second underfill layer 480 may be disposed between the third semiconductor chip 400 and the interposer 500. The first underfill layer 380 and the second underfill layer 480 may surround the first connection terminal 190 in FIG. 7 and the third connection terminal 440, respectively. The system 800 may further include a package molding layer 900 surrounding side surfaces of the semiconductor package 1000 and the third semiconductor chip 400 on the interposer 500. The package molding layer 900 may include, for example, EMC.

A plurality of system connection terminals 540 may be respectively attached to the plurality of first lower pads 524. The plurality of system connection terminals 540 may electrically connect the interposer 500 to the main board 600.

The main board 600 may include a base board layer 610, and a plurality of second upper pads 622 and a plurality of second lower pads 624 respectively disposed on upper and lower surfaces of the base board layer 610. In some embodiments, the main board 600 may be and/or may include a printed circuit board. For example, the main board 600 may be and/or may include a multi-layer printed circuit board. The base board layer 610 may include at least one of phenol resin, epoxy resin, and polyimide.

A solder resist layer that exposes the plurality of second upper pads 622 and the plurality of second lower pads 624 may be formed on each of the upper and lower surfaces of the base board layer 610. A plurality of system connection terminals 540 may be respectively connected to the plurality of second upper surface pads 622, and a plurality of external connection terminals 640 may be respectively connected to the plurality of second lower surface pads 624. The plurality of system connection terminals 540 may electrically connect the plurality of first lower surface pads 524 to the plurality of second upper surface pads 622. The plurality of external connection terminals 640 respectively connected to the plurality of second lower surface pads 624 may connect the system 800 to the outside.

In some embodiments, the system 800 may not include the main board 600 and the plurality of external connection terminals 640. In such embodiments, the plurality of system connection terminals 540 of the interposer 500 may function as external connection terminals.

In some embodiments, when the system 800 is used as part of a larger system, the system 800 may be referred to as a main semiconductor package, and the semiconductor package 1000 may be referred to as a sub-semiconductor package.

While the present disclosure has been particularly shown and described with reference to embodiments thereof, it is to be understood that various changes in form and details may be made therein without departing from the spirit and scope of the following claims.

What is claimed is:

1. A semiconductor chip, comprising:
a semiconductor substrate comprising an active surface and an inactive surface opposite to the active surface;
a wiring layer on the active surface;
a front connection pad on the wiring layer;
a lower protective insulating layer at least partially covering the wiring layer and comprising a lower opening that exposes at least a portion of the front connection pad;
an upper protective insulating layer comprising an upper opening communicatively coupled to the lower opening on the lower protective insulating layer, the upper protective insulating layer comprising an organic material;
a connection terminal coupled to the front connection pad through the lower opening and the upper opening; and
an upper cover insulating layer between the connection terminal and the upper protective insulating layer, the upper cover insulating layer comprising an inorganic material.

2. The semiconductor chip of claim 1, wherein the connection terminal spaced apart from the upper protective insulating layer.

3. The semiconductor chip of claim 1, wherein the upper cover insulating layer at least partially covers an upper surface of the upper protective insulating layer.

4. The semiconductor chip of claim 2, wherein the upper cover insulating layer at least partially covers side surfaces of the upper protective insulating layer within the upper opening.

5. The semiconductor chip of claim 4, wherein the upper cover insulating layer extends from the side surfaces of the upper protective insulating layer, and
wherein the upper cover insulating layer at least partially covers side surfaces of the lower protective insulating layer.

6. The semiconductor chip of claim 5, wherein the upper cover insulating layer extends from the side surfaces of the lower protective insulating layer, and
wherein the upper cover insulating layer at least partially covers an upper surface of the front connection pad.

7. The semiconductor chip of claim 1, further comprising:
a lower cover insulating layer between the lower protective insulating layer and the upper protective insulating layer.

8. The semiconductor chip of claim 7, wherein the upper cover insulating layer contacts the lower cover insulating layer, and
wherein the upper cover insulating layer and the lower cover insulating layer comprise a same material.

9. The semiconductor chip of claim 7, wherein the lower cover insulating layer extends between the lower protective insulating layer and the upper protective insulating layer, and
wherein the lower cover insulating layer at least partially covers side surfaces of the lower protective insulating layer.

10. The semiconductor chip of claim 1, wherein the upper protective insulating layer comprises photosensitive polyimide (PSPI), and
wherein the upper cover insulating layer comprises silicon nitride (SiN).

11. A semiconductor chip, comprising:
a semiconductor substrate;
a front connection pad on the semiconductor substrate;
a lower protective insulating layer at least partially covering the semiconductor substrate and comprising a lower opening that exposes at least a portion of the front connection pad;
an upper protective insulating layer comprising an upper opening communicatively coupled to the lower opening on the lower protective insulating layer, the upper protective insulating layer comprising an organic material;
a lower cover insulating layer between the lower protective insulating layer and the upper protective insulating layer;
a connection terminal coupled to the front connection pad through the lower opening and the upper opening and spaced apart from the upper protective insulating layer; and
an upper cover insulating layer between the connection terminal and the upper protective insulating layer, the upper cover insulating layer comprising an inorganic material,
wherein the connection terminal comprises:
a pillar barrier layer contacting the upper cover insulating layer and the front connection pad;
a conductive pillar comprising a pillar base layer on the pillar barrier layer; and
a conductive cap on the conductive pillar.

12. The semiconductor chip of claim 11, wherein the upper cover insulating layer comprises:
an upper top portion at least partially covering an upper surface of the upper protective insulating layer; and
an upper side portion at least partially covering side surfaces of the upper protective insulating layer within the upper opening.

13. The semiconductor chip of claim 12, wherein the upper side portion extends to at least partially cover the side surfaces of the upper protective insulating layer and side surfaces of the lower protective insulating layer,
wherein the upper side portion contacts an upper surface of the front connection pad, and
wherein the upper cover insulating layer further comprises a bottom residual portion at least partially covering a portion of the upper surface of the front connection pad adjacent to the upper side portion.

14. The semiconductor chip of claim 12, wherein the lower protective insulating layer is spaced apart from the upper protective insulating layer,
wherein the lower cover insulating layer is disposed between the lower protective insulating layer and the upper protective insulating layer, and
wherein the lower cover insulating layer contacts the upper cover insulating layer.

15. The semiconductor chip of claim 14, wherein the lower cover insulating layer comprises:
a lower top portion between the lower protective insulating layer and the upper protective insulating layer; and
a lower side portion at least partially covering side surfaces of the lower protective insulating layer.

16. The semiconductor chip of claim 15, wherein the lower side portion extends along between the side surfaces of the lower protective insulating layer and the upper side portion.

17. The semiconductor chip of claim 12, wherein the pillar barrier layer at least partially covers the front connection pad, the upper side portion, and a portion of the upper top portion coupled to the upper side portion, and
wherein the pillar base layer at least partially covers the pillar barrier layer and at least partially fills the lower opening and the upper opening.

18. A semiconductor package, comprising:
a first semiconductor chip comprising:
a first semiconductor substrate comprising a first active surface and a first inactive surface opposite to the first active surface;
a wiring layer on the first active surface;
a first front connection pad on the wiring layer;
a first rear connection pad on the first inactive surface;
a first through electrode electrically coupling the first front connection pad to the first rear connection pad;
a lower protective insulating layer at least partially covering the wiring layer and comprising a lower opening that exposes at least a portion of the first front connection pad;
an upper protective insulating layer comprising an upper opening communicatively coupled to the lower opening on the lower protective insulating layer, the upper protective insulating layer comprising an organic material;
a lower cover insulating layer between the lower protective insulating layer and the upper protective insulating layer; and
an upper cover insulating layer at least partially covering an upper surface and a side surface of the upper protective insulating layer and side surfaces of the lower protective insulating layer, the upper cover insulating layer comprising an inorganic material;
a connection terminal coupled to the first front connection pad through the lower opening and the upper opening and spaced apart from the upper protective insulating layer, the upper cover insulating layer being disposed between the connection terminal and the upper protective insulating layer;
a plurality of second semiconductor chips, each second semiconductor chip of the plurality of second semiconductor chips comprising:
a second semiconductor substrate comprising a second active surface and a second inactive surface opposite to the second active surface;
a second front connection pad on the second active surface;
a second rear connection pad on the second inactive surface; and
a second through electrode electrically coupling the second front connection pad to the second rear connection pad,
wherein the plurality of second semiconductor chips are sequentially stacked on the first inactive surface of the first semiconductor chip; and
an internal connection terminal coupling between the second front connection pad of a lowermost second semiconductor chip at a lowermost end from among the plurality of second semiconductor chips and the first rear connection pad, and coupling between the second front connection pad and the second rear connection pad of different second semiconductor chips from among the plurality of second semiconductor chips,
wherein the connection terminal comprises:
a pillar barrier layer contacting the upper cover insulating layer and the first front connection pad;
a conductive pillar comprising a pillar base layer on the pillar barrier layer at least partially filling the lower opening and the upper opening; and
a conductive cap on the conductive pillar.

19. The semiconductor package of claim 18, wherein the upper cover insulating layer extends from side surfaces of the lower protective insulating layer, and
wherein the upper cover insulating layer at least partially covers an upper surface of the first front connection pad.

20. The semiconductor package of claim 18, wherein the upper cover insulating layer comprises silicon nitride (SiN),
wherein the lower cover insulating layer comprises silicon nitride (SiN),
wherein the upper protective insulating layer comprises photosensitive polyimide (PSPI), and
wherein the pillar barrier layer comprises at least one of titanium (Ti), titanium nitride (TiN), tantalum (Ta), and tantalum nitride (TaN).
